(19) United States
(12) Patent Application Publication
(10) Pub. No.: US 2007/0018160 A1
(43) Pub. Date: Jan. 25, 2007

(54) DISPLAY FOR DISPLAYING PRODUCT-SPECIFIC INFORMATION ON DISPLAY SCREEN

(75) Inventors: Tetsuya IKEMOTO, Tokyo (JP); Shirou MIYAKE, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: MITSUBISHI ELECTRIC CORPORATION, Chiyoda-ku (JP)

(21) Appl. No.: 11/424,737

(22) Filed: Jun. 16, 2006

(30) Foreign Application Priority Data
Jul. 11, 2005 (JP) 2005-201367

(51) Int. Cl. H01L 29/04

(52) U.S. Cl. 257/59

(57) ABSTRACT

When an ID number is “123”, TFTs (those corresponding to the position of “1”, those corresponding to the position of “2” and those corresponding to the position of “3”) are set to have a lower current drive capability than remaining TFTs. In an ID display mode, driving of TFTs is conducted under the conditions in which only the remaining TFTs are driven, not the TFTs corresponding to the position of the ID number, so that the ID number is displayed on a display screen.

### BACKGROUND OF THE INVENTION

1. Field of the Invention

The present invention relates to a display, and more particularly to a liquid crystal display (LCD) having a display screen with a plurality of thin film transistors (TFTs) arrayed in a matrix.

2. Description of the Background Art

In the case where a product malfunctions, product-specific information (hereinafter referred to as “ID number”) is used in order to analyze product histories including the date of manufacture of the product and a manufacturing apparatus so that the cause of malfunction is specified. Particularly, in a system of manufacturing a plurality of TFT-LCD panels from a single mother board, specifying where on the mother board a panel that causes a malfunction is located is important in controlling product quality. Accordingly, an ID number may contain information about the position of each panel on the mother board. According to a conventional method of ID number indication, an ID number is directly printed on a product by laser marking or stamping, or a label with an ID number is affixed to a product. Recent years, however, small mobile equipment such as mobile phones, digital still cameras and digital video cameras is equipped with LCDs in many cases, which has made it difficult to indicate an D number on a product by the conventional method of direct printing or labeling.

Japanese Patent Application Laid-Open No. 11-231280 (1999) (hereinafter referred to as JP11-231280) discloses a liquid crystal display having an identification information storage in a position different from a display area on an LCD panel so that identification information stored in the identification information storage on the display area under specific driving conditions.

Japanese Patent Application Laid-Open No. 2004-258559 (hereinafter referred to as JP2004-258559) discloses a liquid crystal display in which product information is stored in a dedicated wireless identification tag.

However, the liquid crystal display disclosed in the above JP11-231280 arises the need to secure an area for providing the identification information storage in a position different from the display area on the LCD panel, resulting in size increase of the LCD panel as a whole. Further, in the case where a driving circuit causes a failure due to electrostatic force or the like, the identification information stored in the identification information storage cannot be displayed on the display area.

The liquid crystal display disclosed in the above JP2004-258559 uses the dedicated wireless identification tag, which results in cost increase.

### SUMMARY OF THE INVENTION

An object of the present invention is to provide a display capable of displaying an ID number while preventing the device from increasing in size and cost.

According to a first aspect of the present invention, the display includes a display screen with a plurality of thin film transistors arrayed in a matrix. A predetermined one of the plurality of thin film transistors differ from remaining ones of the plurality of thin film transistors in transistor characteristics. Driving of the plurality of thin film transistors is conducted under the conditions in which only one of the predetermined one of the plurality of thin film transistors and the remaining ones of the plurality of thin film transistors is driven, so that product-specific information is displayed on the display screen.

This allows product-specific information to be displayed on the display screen while preventing the device from increasing in size and cost.

According to a second aspect of the invention, the display includes a display panel with a display screen, a driving circuit configured to drive the display panel, a plurality of terminals to which an individual potential pattern is assigned by each product, and a memory in which data on relationship between a potential pattern and product-specific information is stored. Product-specific information corresponding to the potential pattern assigned to the plurality of terminals is read out from the memory to be displayed on the display screen.

This allows product-specific information to be displayed on the display screen while preventing the device from increasing in size and cost.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic view showing the outline of a panel of a TFT-LCD;

FIG. 2 is a block diagram showing the inner configuration of the TFT-LCD shown in FIG. 1;

FIG. 3 is a timing chart showing operating waveforms of the TFT-LCD shown in FIG. 2;

FIG. 4 is a schematic view showing only TFTs extracted from part of a display screen of a TFT-LCD according to a first preferred embodiment of the present invention;

FIG. 5 is a graph showing gate voltage versus drain current characteristics of TFTs;

FIG. 6 is a block diagram showing the configuration of part of a TFT-LCD according to a second preferred embodiment of the invention;

FIG. 7 is a top view showing the configuration of terminals of a driving circuit shown in FIG. 6;

FIGS. 8 and 9 are schematic views each showing the configuration of terminals provided on an array substrate of a liquid crystal panel;

FIG. 10 shows part of an ID table stored in a memory shown in FIG. 6; and

FIGS. 11 and 12 are schematic views each showing one of manufacturing steps of the TFT-LCDs according to the first and second preferred embodiments.

### DESCRIPTION OF THE PREFERRED EMBODIMENTS

### First Preferred Embodiment

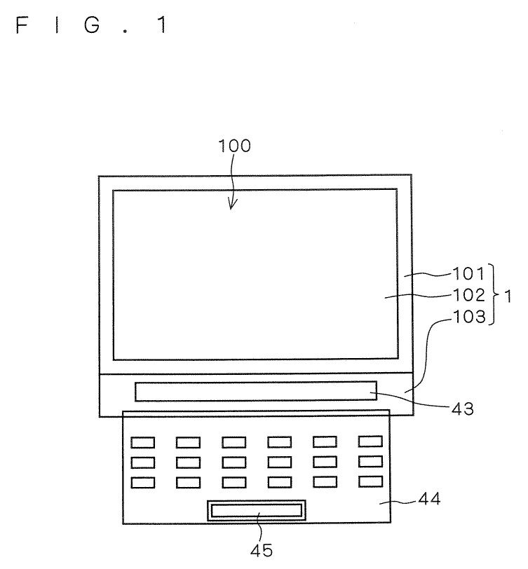

FIG. 1 is a schematic view showing the outline of a panel portion of a small TFT-LCD used as a flat panel display. A liquid crystal panel 1 is configured such that a liquid crystal layer 102 is interposed between a common electrode substrate 101 and an array substrate 103, and is provided with a display area 100 of predetermined size. The array substrate 103 has TFTs and interconnect wires configured with a predetermined pattern on a glass substrate. The common electrode substrate 101 has a glass substrate with common electrodes configured with a predetermined pattern thereon.

A driving circuit 43 is in the form of IC chip with a control circuit, a gate driver IC, a source driver IC and the like integrated thereon so as to allow for reduction in weight, size and thickness, and is mounted directly on the array substrate 103. The mounted driving circuit 43 may be replaced with a new driving circuit 43. Input voltage and input signal to the TFT-LCD are supplied to the driving circuit 43 through an input connector 45 mounted on an FPC (flexible printed circuit) 44. On the FPC 44, electronic components such as capacitors are mounted.

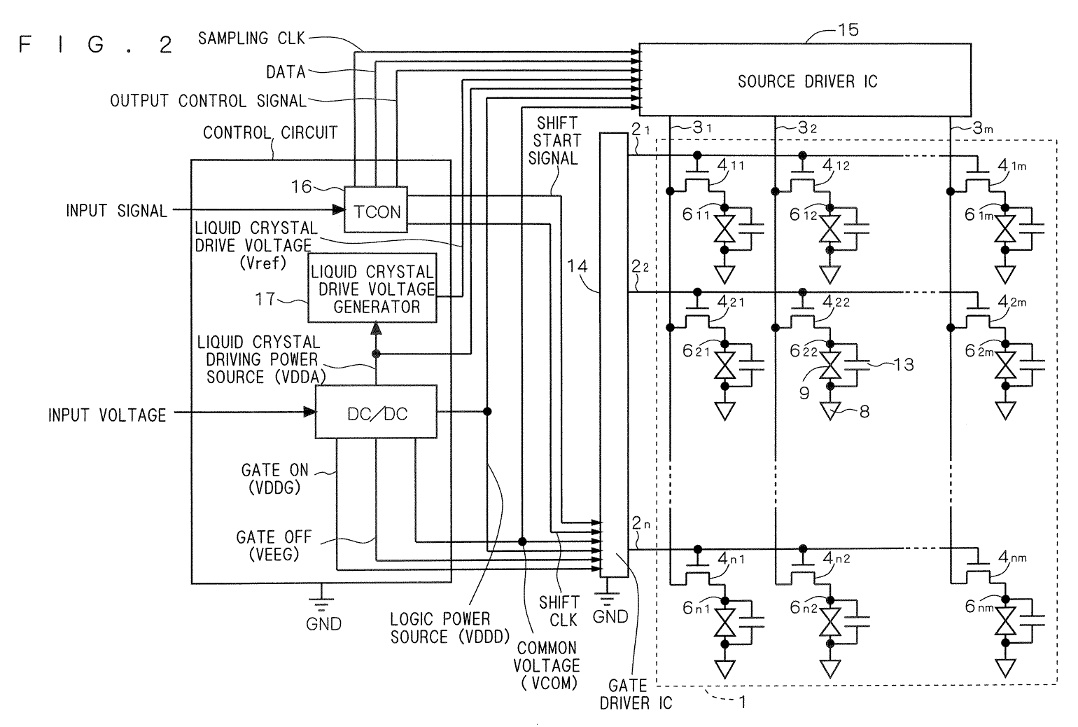

FIG. 2 is a block diagram showing the inner configuration of the TFT-LCD shown in FIG. 1. The liquid crystal panel 1 has a plurality of (n in the example shown in FIG. 2) gate lines 2₁, 2₂, . . . , 2ₙ extending along the X axis (in the row direction) and a plurality of (m in the example shown in FIG. 2) source lines 3₁, 3₂ . . . , 3ₙ extending along the Y axis (in the column direction). Provided in correspondence with respective interconnections of the gate lines 2₁, 2₂, . . . , 2ₙ and source lines 3₁, 3₂, . . . , 3ₘ are TFTs 4 (4₁₁, 4₁₂, . . . , 4₁ₘ, 4₂₁, 4₂₂, . . . , 4₂ₘ, 4ₙ₁, 4ₙ₂, . . . , 4ₙₘ) made of amorphous silicon (a-Si), and pixels are provided in correspondence with the TFTs 4, respectively. In other words, the display screen of the liquid crystal panel 1 has a plurality of TFTs 4 and a plurality of pixels arrayed in a matrix. Each pixel has a liquid crystal layer 9 (corresponding to the liquid crystal layer 102 shown in FIG. 1) interposed between a common electrode 8 (corresponding to the common electrode substrate 101 shown in FIG. 1) and a pixel electrode 6 (6₁₁, 6₁₂, . . . , 6₁ₘ, 6₂₁, 6₂₂, . . . , 6₂m, 6ₙ₁, 6ₙ₂, . . . , 6ₙₘ) provided for each pixel as well as a storage capacitor 13.

Each of the TFTs 4 has its gate electrode connected to a corresponding one of the gate lines 2₁, 2₂, . . . , 2ₙ, its source electrode connected to a corresponding one of the source lines 3₁, 3₂, . . . , 3ₘ, and its drain electrode connected to a corresponding one of the pixel electrodes 6. For instance, the TFT 4₂₂ has its gate electrode connected to the gate line 2₂, its source electrode connected to the source line 32, and its drain electrode connected to the pixel electrode 6₂₂.

The gate lines 2₁, 2₂, . . . , 2ₙ are connected to a gate driver IC 14, and the source lines 3₁, 3₂, . . . , 3ₘ are connected to a source driver IC 15. The gate driver IC 14 and source driver IC 15 are controlled by a timing controller (TCON) 16 for controlling timing. The TCON 16 receives an input signal containing image data from an externally-connected computer or the like.

FIG. 3 is a timing chart showing operating waveforms of the TFT-LCD shown in FIG. 2. A liquid crystal drive voltage (Vref) is supplied to the source driver IC 15 from a liquid crystal drive voltage generator 17. The source driver IC 15 samples DATA on the gate line 2₁ input from the TCON 16 in accordance with a sampling CLK and stores the sampled DATA.

After the DATA on the gate line 2₁ is stored in the source driver IC 15, the gate driver IC 14 drives the gate line 2₁ on the basis of a shift start signal and a shift CLK input from the TCON 16. All of the TFTs 4₁₁, 4₁₂, . . . , and 4₁ₘ connected to the gate line 2₁ are thereby turned on.

Immediately thereafter, all the source lines 3₁, 3₂, . . . , 3ₘ are driven by the source driver IC 15. A liquid crystal drive voltage obtained by converting the DATA stored in the source driver IC 15 is supplied to each of the pixel electrodes 6₁₁, 6₁₂, . . . , 6₁ₘ through the source and drain electrodes of each of the TFTs 4₁₁, 4₁₂, . . . , and 4₁ₘ, and the supplied voltage is accumulated in the liquid crystal layer 9 and storage capacitor 13 of each pixel.

Then, the source driver IC 15 starts sampling of DATA on the next gate line 2₂ under the control of the TCON 16.

The above operation is repeated to thereby display an image on the display screen of the liquid crystal panel 1 on the basis of an input signal input from the externally-connected computer or the like.

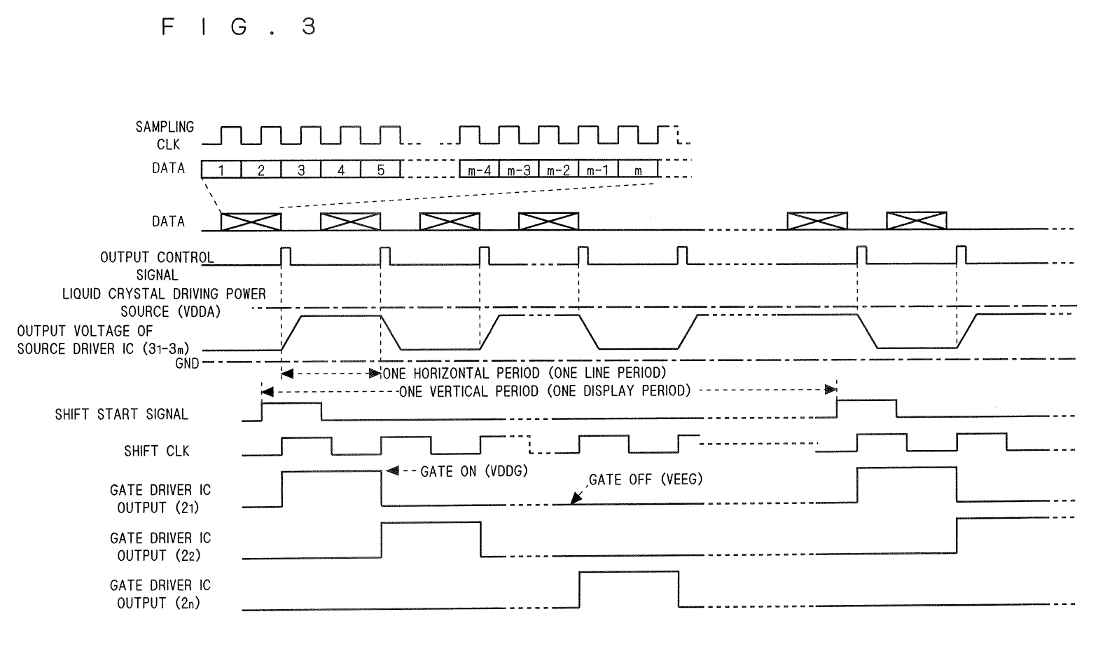

FIG. 4 is a schematic view showing only TFTs 4 extracted from part of the display screen of the TFT-LCD according to this first preferred embodiment. FIG. 4 shows 56 TFTs in total, i.e., TFTs 4₁₁-4₁₈, 4₂₁-4₂₈, 4₃₁-4₃₈, 4₄₁-4₄₈, 4₅₁-4₅₈, 4₆₁-4₆₈ and 4₇₁-4₇₈. The TFT-LCD according to the present embodiment is configured such that, when displaying an ID number on the display screen, those of the TFTs 4 that are provided in a position corresponding to the ID number have a lower current drive capability than the rest of the TFTs 4 that are provided in a position not corresponding to the ID number. In the example shown in FIG. 4, the ID number is “123”, and the TFTs 4₂₁, 4₃₁, 4₄₁, 4₅₁ and 4₆₁ corresponding to the display position of “1”, the TFTs 4₂₃-4₂₅, 4_{35,} 4₄₄, 4₅₃ and 4₆₃-4₆₅ corresponding to the display position of “2”, and the TFTs 4₂₆-4₂₈, 4_{38,} 4₄₆-4₄₈, 4₅₈ and 4₆₆-4₆₈ corresponding to the display position of “3” are set to have a lower current drive capability than the rest of the TFTs 4. To reduce the current drive capability, the TFTs 4 may be reduced in channel width or increased in channel length, for example. Batch exposure may be conducted on the whole mother board using a large mask having a different pattern for each of liquid crystal panels, so that the liquid crystal panels have different transistor characteristics from one another.

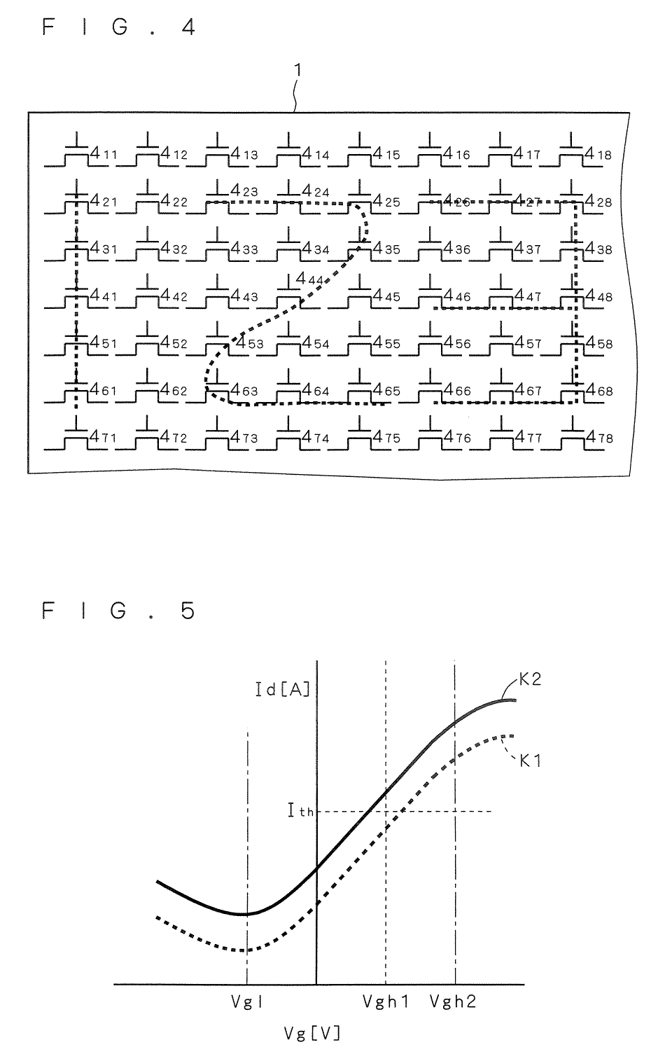

FIG. 5 is a graph showing gate voltage (Vg) versus drain current (Id) characteristics of the TFTs 4. A characteristic curve K1 is of a TFT 4 provided in a position corresponding to the ID number (hereinafter referred to as “TFT 4x”), and a characteristic curve K2 is of a TFT 4 provided in a position not corresponding to the ID number (hereinafter referred to as “TFT 4y”). The current value Iₜₕ is the minimum value of the drain current required to be supplied to the pixel electrodes 6 for making display.

In a mode of displaying an image on the basis of an input signal from the outside (hereinafter referred to as “normal display mode”), the TFTs 4 are driven setting the turn-on voltage at a gate voltage Vgh2. When the gate voltage Vhg2 is applied, the drain current in each of the TFTs 4x and 4y exceeds the current value Iₜₕ, which arises no problem in displaying an image on the display screen.

On the other hand, in a mode of displaying an ID number (hereinafter referred to as “ID display mode”), the TFTs 4 are driven setting the turn-on voltage at a gate voltage Vgh1 lower than the gate voltage Vgh2. When the gate voltage Vgh1 is applied, the drain current in the TFT 4y exceeds the current value Ith, while the drain current in the TFT 4x does not. Therefore, a sufficient drain current is supplied to a pixel electrode 6 connected to the TFT 4y, whereas an insufficient drain current is supplied to a pixel electrode 6 connected to the TFT 4x. As a result, in the case of a normally white liquid crystal display displaying a pixel brighter with decreasing voltage in a corresponding pixel electrode 6, a pixel corresponding to the TFT 4x is displayed brighter than a pixel corresponding to the TFT 4y, so that the ID number is displayed on the display screen. In other words, in the ID display mode, driving of the TFTs 4 is conducted under the conditions in which only the TFT 4y is driven, not the TFT 4x, so that the ID number is displayed on the display screen.

In the case of a normally black liquid crystal display displaying a pixel brighter with increasing voltage in a corresponding pixel electrode 6, an ID number is displayed on the display screen by setting the TFT 4x to have a higher current drive capability than the TFT 4y, contrarily to the above example, and driving only the TFT 4x in the ID display mode.

Two kinds of turn-on voltages are used in the above description, however, two kinds of turn-off voltages may be used for driving only one of the TFTs 4x and 4y in the ID display mode.

As described, the TFT-LCD according to the present embodiment is configured such that the TFT 4x provided in the position corresponding to the ID number is set to have a lower current drive capability than the TFT 4y provided in the position not corresponding to the ID number. Besides, driving of the TFTs 4 is conducted under the conditions in which only the TFT 4y is driven, not the TFT 4x, in the ID display mode to thereby display the ID number on the display screen. Accordingly, unlike the liquid crystal display disclosed in the aforementioned JP11-231280, it is not necessary to provide an identification information storage in a position different from the display area on the liquid crystal panel 1, which can avoid upsizing of the liquid crystal panel 1 as a whole. In the case where the driving circuit 43 causes a failure due to electrostatic force or the like, the driving circuit 43 may be replaced with a new one, so that the ID number is displayed on the display screen. Further, the TFT-LCD according to the present embodiment does not require a dedicated wireless identification tag, which can therefore be implemented at relatively low costs.

### Second Preferred Embodiment

FIG. 6 is a block diagram showing the configuration of part of a TFT-LCD according to a second preferred embodiment of the invention. The driving circuit 43 for driving the liquid crystal panel 1 has a non-volatile memory 47 in which an ID table to be described later is stored.

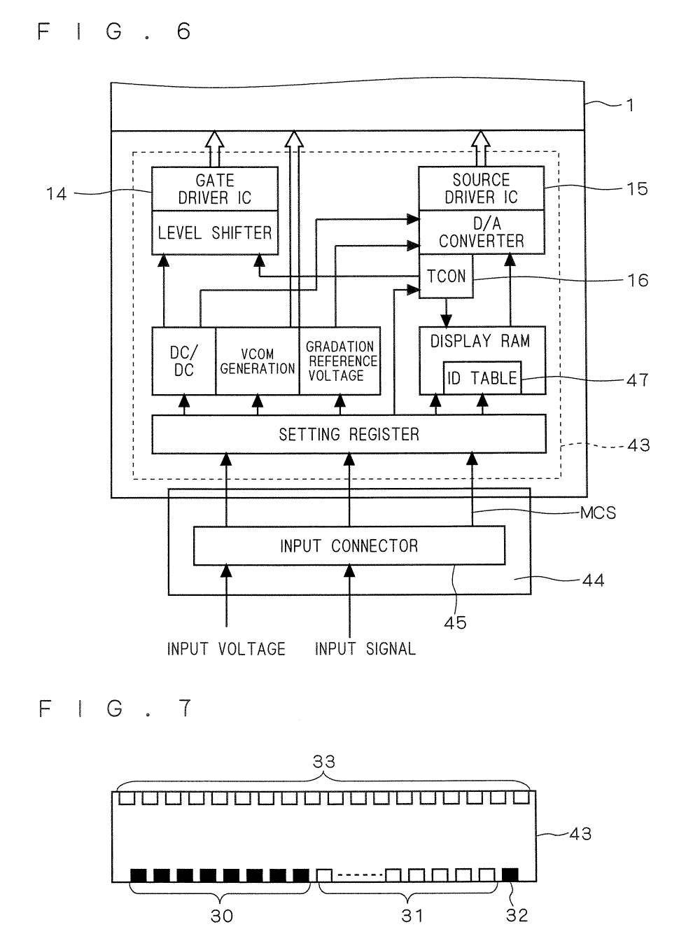

FIG. 7 shows terminals of the driving circuit 43. The terminals 30 receive an individual potential pattern corresponding to the liquid crystal panel 1 from the array substrate 103. Terminals 31 receive an input signal, an input voltage and the like, from the outside. A terminal 32 receives an MCS signal for switching between the normal display mode and ID display mode, from the outside. Terminals 33 are connected to the array substrate 103.

With reference to FIGS. 2, 6 and 7, in the normal display mode, the source driver IC 15 drives the source lines 3₁, 3₂, . . . , 3ₘ on the basis of an input signal input from the outside through the terminals 31. Normal image display is thereby offered.

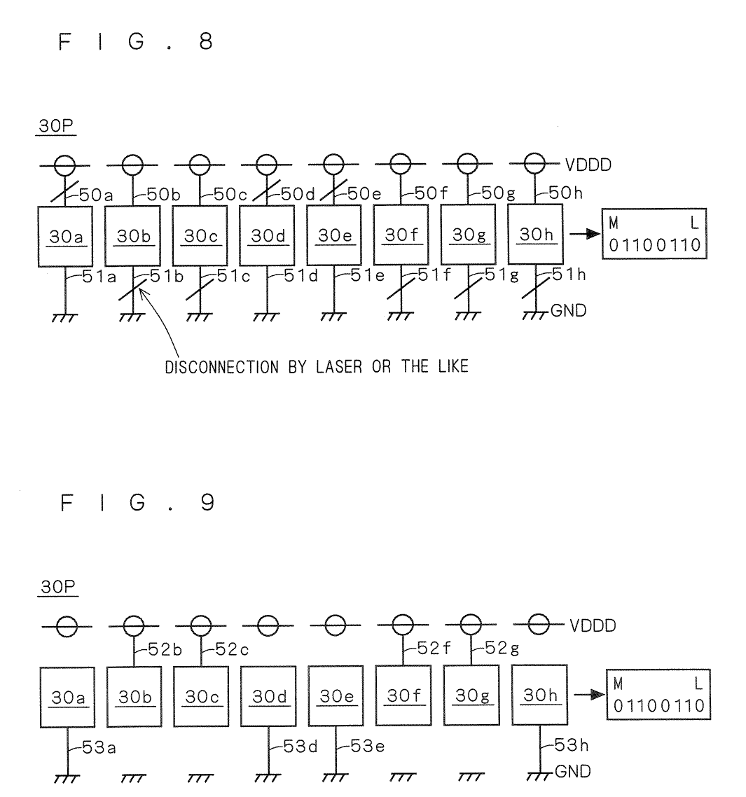

FIGS. 8 and 9 each show the configuration of terminals 30P provided on the array substrate 103 of the liquid crystal panel 1. Directly mounting the driving circuit 43 on the array substrate 103 allows the terminals 30 shown in FIG. 7 and the terminals 30P shown in FIGS. 8 and 9 to be connected to one another. The terminals 30P include a plurality of (8 in the examples shown in FIGS. 8 and 9) terminals 30a to 30h. The terminals 30a to 30h correspond to the eight terminals 30 shown in FIG. 7, respectively.

With reference to FIG. 8, interconnect lines 50 (50a-50h) are provided between a source potential VDDD of a logic power source and the terminals 30a to 30h, respectively, and interconnect lines 51 (51a-51h) are provided between a ground potential GND and the terminals 30a to 30h, respectively. One of the interconnect lines 50 and 51 is disconnected by laser or the like at each of the terminals 30a to 30h. In the example shown in FIG. 8, the interconnect lines 50a, 51b, 51c, 50d, 50e, 51f, 51g and 51h are disconnected. Accordingly, letting the terminal 30a be MSB, terminal 30h be LSB, source potential VDDD be “1” of binary number, and ground potential GND be “0” of binary number, the terminals 30P has a potential pattern corresponding to digital data of “01100110”.

The potential at each of the terminals 30a to 30h may be determined using fuse elements instead of laser disconnection to disconnect predetermined fuse elements according to an ID number after pattern formation.

With reference to FIG. 9, one of an interconnect line 52 connected to the source potential VDDD and an interconnect line 53 connected to the ground potential GND is connected to each of the terminals 30a to 30h. In the example shown in FIG. 9, interconnect lines 52b, 52c, 52f and 52g are connected to the terminals 30b, 30c, 30f and 30g, respectively, and interconnect lines 53a, 53d, 53e and 53h are connected to the terminals 30a, 30d, 30e and 30h, respectively. Accordingly, letting the terminal 30a be MSB, terminal 30h be LSB, source potential VDDD be “1” of binary number and ground potential GND be “0” of binary number, the terminals 30P has a potential pattern corresponding to digital data of “0100110”.

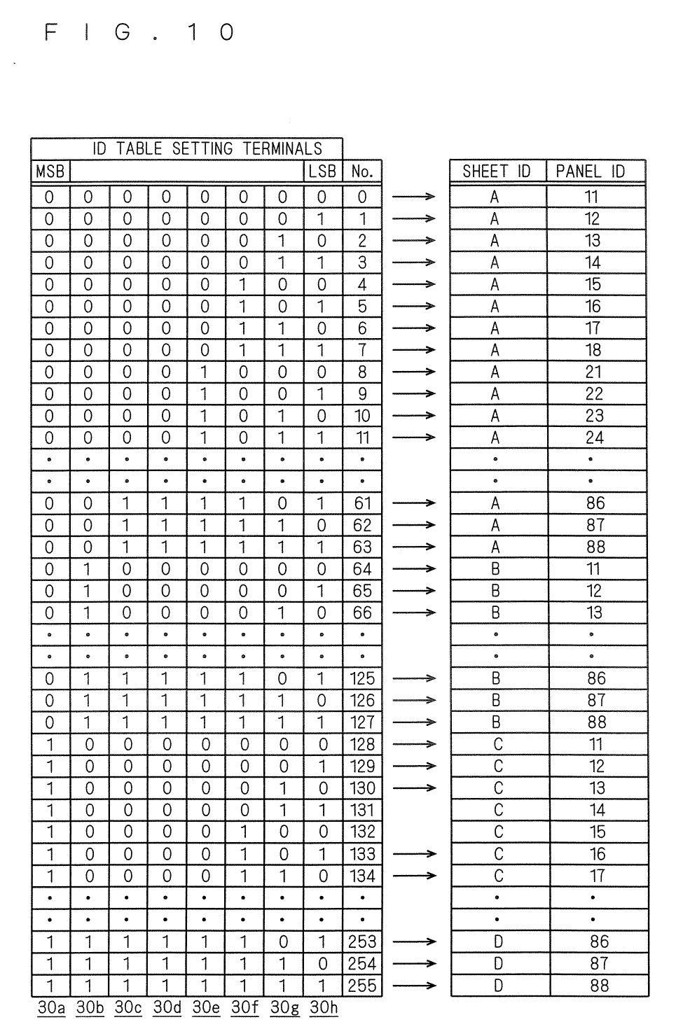

FIG. 10 shows part of an ID table stored in the memory 47 shown in FIG. 6. The ID table contains relationships between 8-bit digital data and ID number. An ID number is made up of a sheet ID (A to D) which is identification information about a mother board and a panel ID (11 to 18, 21 to 28, . . . , and 81 to 88) which is identification information about a panel in the mother board. For instance, an ID number in the case where 8-bit digital data is “00001011” (“11” in decimal notation) is “A24” made up of sheet ID of “A” and panel ID of “24”.

In the ID display mode in which the switching signal MCS is input to the terminals 32, digital data assigned to the terminals 30P is input to the TCON 16 through the terminals 30, and the TCON 16 reads out an ID number corresponding to the digital data input at the terminals 30, from the memory 47, referring to the ID table stored in the memory 47. Then, the ID number read out from the memory 47 is displayed on the display screen of the liquid crystal panel 1. In the present embodiment, the driving circuit 43, when it causes a failure, may be replaced, so that the ID number can be displayed on the liquid crystal panel 1.

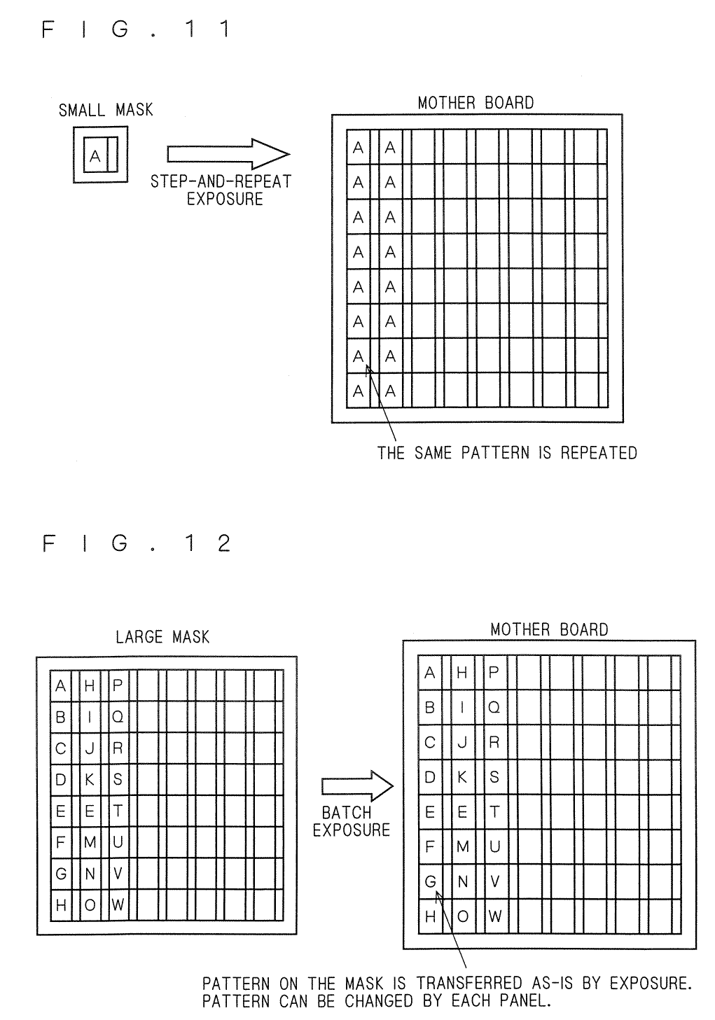

FIG. 11 is a schematic view showing one of manufacturing steps of the TFT-LCDs according to the first and second preferred embodiments. Using a stepper for step-and-repeat exposure, a plurality of liquid crystal panels 1 are manufactured from a single mother board. Using a stepper, the same pattern is transferred onto each of the liquid crystal panels 1 by exposure, and thereafter, a potential pattern is individually formed on each of the liquid crystal panels 1. In the case of pattern transfer conducting step-and-repeat exposure by the stepper method using a small mask, it is difficult to vary transistor characteristics by each of the liquid crystal panels 1, however, this problem can be solved by this second preferred embodiment.

In the case of forming the terminals 30P as shown in FIG. 8, the terminals 30a to 30h and interconnect lines 50a to 50h and 51a to 51h are formed by step-and-repeat exposure using a stepper, and then, one of the interconnect lines 50 and 51 is disconnected by laser or the like by each of the liquid crystal panel 1 according to an ID number.

In the case of forming the terminals 30P as shown in FIG. 9, the terminals 30a to 30h are formed by step-and-repeat exposure using a stepper, and then, individual exposure is conducted on one or a plurality of liquid crystal panels 1, or batch exposure is conducted on the whole mother board (with a different mask pattern for each of the liquid crystal panels 1) to thereby form either of the interconnect lines 52 and 53 on each of the liquid crystal panels 1 according to an ID number.

When a stepper is not used, the terminals 30a to 30h and interconnect lines 50 and 51 shown in FIG. 8 can be formed by individual exposure on one or a plurality of liquid crystal panels 1 or batch exposure on the whole mother board as shown in FIG. 12. Likewise, when a stepper is not used, the terminals 30a to 30h and interconnect lines 52 and 53 shown in FIG. 9 can be formed by individual exposure on one or a plurality of liquid crystal panels 1 or batch exposure on the whole mother board (with a different mask pattern used for each of the liquid crystal panels 1).

The above description has been directed to the case of assigning 8-bit digital data to the terminals 30 using the eight terminals 30a to 30h; however, needless to say, the amount of information of an ID number can be increased using a greater number of terminals.

Further, combination of the first and second preferred embodiments allows display of a greater amount of manufacturing information. For instance, positional information about a mother board is obtained according to the first preferred embodiment, and sheet identification and device history management are made by the ID table of the driving circuit 43 according to the second preferred embodiment, so that a greater amount of manufacturing information can be displayed without increasing the contents of the ID table.

As described, in the TFT-LCD according to the present embodiment, the ID table is stored in the memory 47 in the driving circuit 43, an individual potential pattern per product is assigned to the terminals 30P. In the ID display mode, an ID number corresponding to a potential pattern assigned to the terminals 30P are read out from the memory 47 referring to the ID table, and the ID number is displayed on the display screen on the liquid crystal panel 1. Therefore, unlike the liquid crystal display disclosed in the aforementioned JP 11-231280, it is not necessary to provide an identification information storage in a position different from the display area on the liquid crystal panel 1, which can avoid upsizing of the liquid crystal panel 1 as a whole. Further, the TFT-LCD according to the present embodiment does not require a dedicated wireless identification tag unlike the liquid crystal display disclosed in the aforementioned JP2004-258559, which can therefore be implemented at relatively low costs.

While the invention has been shown and described in detail, the foregoing description is in all aspects illustrative and not restrictive. It is therefore understood that numerous modifications and variations can be devised without departing from the scope of the invention.

What is claimed is:

1. A display comprising a display screen with a plurality of thin film transistors arrayed in a matrix, wherein
a predetermined one of said plurality of thin film transistors differ from remaining ones of said plurality of thin film transistors in transistor characteristics, and
driving of said plurality of thin film transistors is conducted under the conditions in which only one of said predetermined one of said plurality of thin film transistors and said remaining ones of said plurality of thin film transistors is driven, so that product-specific information is displayed on said display screen.

2. A display comprising:
a display panel with a display screen;
a driving circuit configured to drive said display panel;
a plurality of terminals to which an individual potential pattern is assigned by each product; and
a memory in which data on relationship between a potential pattern and product-specific information is stored, wherein
product-specific information corresponding to said potential pattern assigned to said plurality of terminals is read out from said memory to be displayed on said display screen.
